(19) United States
(12) Patent Application Publication
(10) Pub. No.: US 2017/0275054 A1
(43) Pub. Date: Sep. 28, 2017

(54) STANDUP FLEXIBLE POUCH HAVING METALLISED GUSSET AND WINDOW

(71) Applicant: Pouch Pac Innovations, LLC, Sarasota, FL (US)

(72) Inventor: R. Charles Murray, Sarasota, FL (US)

(73) Assignee: Pouch Pac Innovations, LLC

(21) Appl. No.: 15/468,455

(22) Filed: Mar. 24, 2017

Related U.S. Application Data
(60) Provisional application No. 62/313,163, filed on Mar. 25, 2016.

(51) Int. Cl. B65D 30/08; B65D 85/00; C23C 14/14; B65D 33/04; B65D 75/00; C23C 16/06; B65D 35/10; B65D 30/20

(52) U.S. Cl. CPC B65D 31/04; B65D 35/10; B65D 85/70; B65D 31/10; B65D 33/04; B65D 75/008; C23C 16/06; C23C 14/14

(57) ABSTRACT

A flexible pouch for containing a product. The flexible pouch may include a pouch body formed from an opaque multilayer panel configured to protect the product contained in the flexible pouch from oxygen ingress into the flexible pouch. A gusset formed from a multilayer panel comprising an opaque portion and a transparent window portion may also be included, and the transparent window portion allows for configured for viewing the product within the flexible pouch.

### CROSS-REFERENCE TO RELATED APPLICATION

This application claims priority of U.S. Provisional Patent Application Ser. No. 62/313,163 filed on Mar. 25, 2016, which is incorporated in its entirety herein by reference.

### FIELD OF TECHNOLOGY

The present application relates to a standup flexible pouch for packaging product, and more specifically, to a standup flexible pouch with a bottom gusset having a clear or see-through window.

### BACKGROUND

Standup pouches for storing fluid and/or dry products such as a liquid, granular material, powder and the like are known. Such standup pouches may be formed from one or more laminated panels with multiple layers that include a layer of metal, e.g., a layer of aluminum, that prevents the ingress of oxygen into the flexible pouch, protects product within the flexible pouch from being exposed to light, etc. The layer of aluminum in the laminate material renders the laminate material opaque, i.e., an individual cannot see into the pouch. However, it may be desirable for consumers to view a product within the pouch. For example, it may be desirable for consumers to visually inspect an edible product within a pouch for freshness and color. Accordingly, a standup pouch that protects a product therein from oxygen ingress and/or light, but allows a consumer to visually inspect a product within the pouch would be desirable.

### SUMMARY

A flexible pouch for containing a product is provided. The flexible pouch includes a pouch body formed from an opaque multilayer panel that is configured to protect the product contained in the flexible pouch from the ingress of oxygen into the flexible pouch. The flexible pouch also includes a gusset formed from a multilayer panel with an opaque portion and a transparent window portion. The transparent window portion allows a consumer to view product within the flexible pouch. The transparent window portion of the gusset may include a plurality of transparent polymer layers and the opaque portion may be metallized with a metal film extending over the plurality of transparent polymer layers. The plurality of transparent polymer layers may include a first layer formed from polyethylene terephthalate, a second layer formed from nylon and a third layer formed from polyethylene. The metal film may be formed from aluminum and extends over the polyethylene. The opaque multilayer panel from which the pouch body is formed may include a first transparent polymer layer, a layer of metal, a second transparent polymer layer and a third transparent polymer layer. The first transparent polymer layer may be formed from polyethylene terephthalate, the layer of metal may be formed from aluminum, the second transparent polymer layer may be formed from nylon and the third transparent polymer layer may be formed from polyethylene.

A process for making a flexible pouch is also included. The process includes forming a pouch body from an opaque multilayer panel and forming a gusset from a multilayer panel that includes an opaque portion and a transparent window portion. The gusset is sealed to the pouch body to form the flexible pouch and the transparent window portion of the gusset allows an individual, e.g., a consumer, to view a product within the flexible pouch. The opaque portion of the multilayer panel is formed by a metal layer extending across the multilayer panel. In embodiments, the metal layer is formed on the opaque portion by vapor deposition and the transparent window portion of the multilayer panel is masked while vapor depositing the metal layer onto the opaque portion. The opaque multilayer panel from which the pouch body is formed may include a polyethylene terephthalate layer, an aluminum layer, a nylon layer, and a polyethylene layer. In embodiments, the metal layer is sandwiched between the polyethylene terephthalate layer and the nylon layer.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 is a front perspective view of a standup pouch having a gusset with a transparent window portion according to one or more embodiments disclosed and described herein;

FIG. 2 is a cross-sectional view of a laminated panel used to form a pouch body for the standup pouch in FIG. 1;

FIG. 3 is a bottom view of the gusset for the standup pouch in FIG. 1 according to one or more embodiments disclosed and described herein;

FIG. 4 is a cross-sectional view of section 4-4 in FIG. 3; and

FIG. 5 depicts a process for making a gusset with a transparent window portion according to one or more embodiments disclosed and described herein.

### DETAILED DESCRIPTION

A standup flexible pouch with a pouch body that is opaque and a gusset that has a transparent window portion is provided. The pouch body may be formed from one or more opaque multilayer panels that include a metal layer that inhibits the ingress of oxygen into the flexible pouch and/or exposure of product within the flexible pouch to light. That is, the metal layer inhibits diffusion of oxygen and/or prevents light from passing through the one or more opaque multilayer panels. It is understood that such an opaque pouch body does not allow a consumer to view the product within the flexible pouch. However, the gusset with the transparent window portion allows a consumer to see through and view the product within the flexible pouch. The gusset may include an opaque portion in addition to the transparent window portion. The transparent window portion formed by one or more polymer layers and the opaque portion may be formed from a metal film extending over the one or more polymer layers.

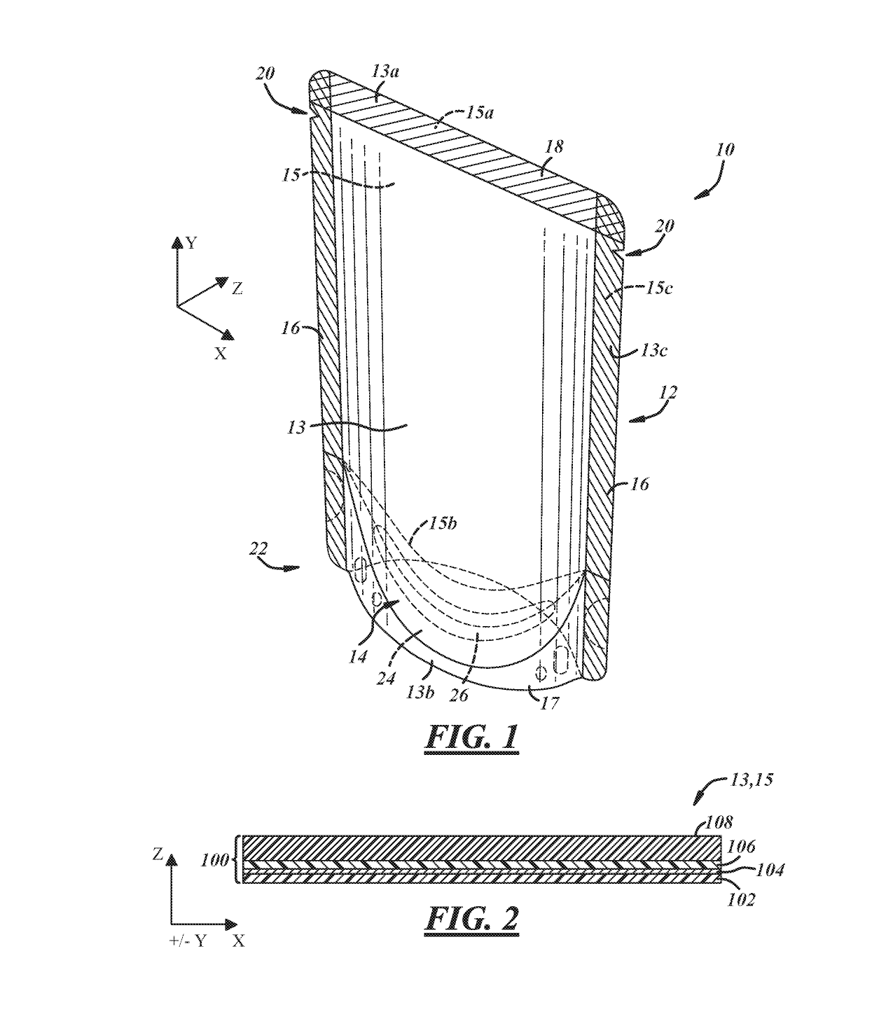

Referring to FIG. 1, a standup flexible pouch with a gusset that provides for the pouch to stand on its own is depicted. The flexible pouch includes a main pouch body that is opaque and may be formed from multiple layers of polymer materials and at least one metal layer. Positioned at a bottom end of the flexible pouch body is the gusset. The gusset includes an opaque portion that does not allow light to pass through and thereby cannot be seen through by an individual. The gusset also includes a transparent window portion that allows light to pass through and thereby can be seen through by an individual. The gusset may be formed from multiple layers of polymer materials and the opaque portion may have a metal film extending across the multiple layers of polymer materials and the transparent window portion may not have a metal film extending across the multiple layers of polymer materials. The metal film may be any metal film or alloy that inhibits oxygen ingress through illustratively including but not limited to aluminum (Al), nickel (Ni), titanium (Ti), alloys thereof, stainless steel, and the like.

Still referring to FIG. 1, a standup flexible pouch (flexible pouch) is generally illustrated at reference numeral 10. The flexible pouch 10 includes a pouch body 12 and a gusset 14. In embodiments, the gusset 14 is a standup gusset, i.e., the gusset 14 is sealed to a bottom portion 22 of the pouch body and is shaped and dimensioned to afford for the flexible pouch 10 to stand on its own in an upright position as depicted in FIG. 1. The pouch body 12 may include a front panel 13 and a back panel 15. The front panel 13 and back panel 15 include an upper edge 13a, 15a, respectively, and a bottom edge 13b, 15b, respectively. A pair of side edges 13c, 15c of the front panel 13 and back panel 15, respectively, extend between the upper edges 13a, 15a and bottom edges 13b, 15b. The pouch body 12 may be formed by sealing the side edges 13c, 15c of the front panel 13 and back panel 15, respectively, together to form side seals 16. The pouch body 12 may include two side seals 16 if made from two separate panels or one single side seal 16 if made from one panel that is folded. In an example of a pouch made from one panel, the side edges of the panel may be joined along a center seam. The seam may be a flat seam. In an example of a pouch formed using two panels of material, the edges are joined along two side seams as depicted in FIG. 1.

A top seal 18 is formed by sealing the upper edge 13a of the front panel 13 to the upper edge 15a of the back panel 15. A tear notch 20 may be formed on the pouch body 12 below the top seal 18. The tear notch 20 may be a weakened portion formed to facilitate tearing of the pouch body 12 in order to allow access into the interior of the pouch body 12. It should be appreciated that the flexible pouch 10 may include other types of openers, openings, etc., to grant access into the interior of the pouch body 12, illustratively including but not limited to caps, zippers, taps, spouts, other types of fitments, etc.

The gusset 14 is sealed to the bottom portion 22 at the bottom edges 13b, 15b of the front panel 13 and back panel 15, respectively, opposite the top seal 18 of the pouch body 12. The gusset of FIG. 1 is shown in an inserted position and has an opaque portion 24 and a transparent window portion 26 as discussed in greater detail below.

Referring now to FIG. 2, a cross-sectional view of the front panel 13 and/or back panel 15 is depicted. The view of the front panel 13 and/or back panel 15 is in the thickness direction (Y direction depicted in the figures). The front panel 13 and/or back panel 15 is formed from a multilayer panel 100. The multilayer panel 100 may include a first transparent polymer layer 102, a metal layer 104, a second transparent polymer layer 106 and a third transparent polymer layer 108. In embodiments, the first transparent polymer layer 102 is formed from polyethylene terephthalate (PET), the metal layer 104 is formed from Al, the second transparent polymer layer 106 is formed from nylon (NY) and the third transparent polymer layer 108 is formed from polyethylene (PE). In some embodiments, the layer of PE is formed from a linear low density polyethylene (LLDPE).

In embodiments, the first transparent polymer layer 102 formed from PET may have a thickness between about 12 micrometers (microns) and about 15 microns. The metal layer 104 formed from Al may have a thickness between about 7 microns and about 9 microns and the second transparent polymer layer 106 formed from NY may have a thickness between about 12 microns and about 18 microns. The third transparent polymer layer 108 formed from PE, and preferably formed from LLDPE, may have a thickness between about 70 microns and about 200 microns. For example, a first transparent polymer layer 102 formed from PET layer may have a thickness of 12 microns, a metal layer 104 formed from Al may have a thickness of 8 microns, a second transparent polymer layer 106 formed from NY may have a thickness of 15 microns and a third transparent polymer layer 108 formed from LLDPE may have a thickness of 90 microns. It should be understood that the metal layer 104 provides protection from light, moisture and oxygen ingress into the flexible pouch 10 and thereby assists in maintaining a product within the flexible pouch 10 in a desired condition. It should also be understood, that the multilayer panel 100 is opaque and thus cannot be seen through by a consumer and thus a product within the flexible pouch 10 cannot be viewed or seen through the pouch body 12.

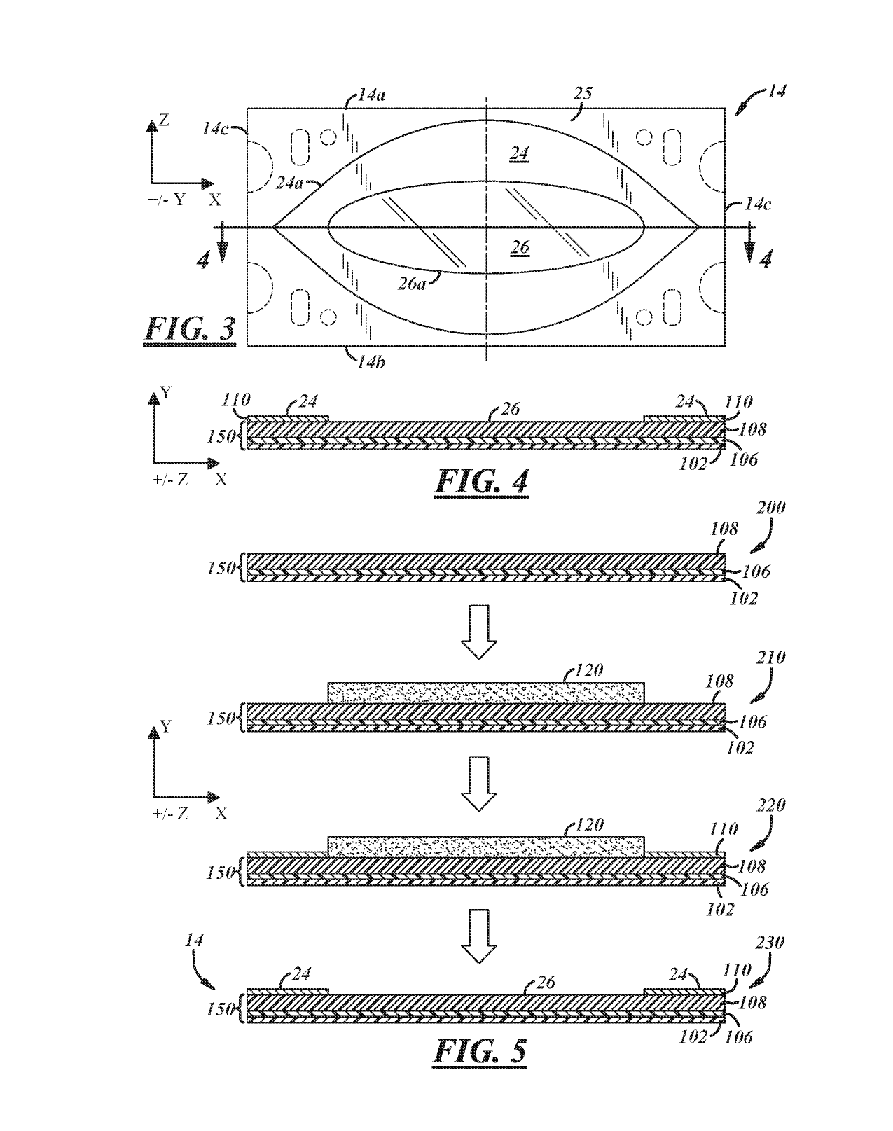

Referring now to FIG. 3, the gusset 14 is shown from a bottom view (Y direction depicted in the figures). The gusset 14 has an opaque portion 24 and a transparent window portion 26. In embodiments, the transparent window portion 26 is positioned in a central region of the gusset 14 as depicted in FIG. 3. The transparent window portion 26 allows an individual to see there through and thereby see a product contained within the flexible pouch 10. The opaque portion may extend from an edge 26a of the transparent window portion 26 to outer side edges 14a, 14b and end edges 14c of the gusset 14. In the alternative, the opaque portion 24 may extend from the edge 26a of the transparent window portion 26 to an outer edge 24a with a region 25 between the outer edge 24a of the opaque portion 24 and the outer side edges 14a, 14b and end edges 14c not being opaque but sealed to the pouch body 12 along bottom edges 13b, 15b of the front panel 13 and back panel 15, respectively.

Referring now to FIG. 4, a cross section of section 4-4 of the gusset 14 depicted in FIG. 3 with the opaque portion 24 and the transparent window portion 26 is shown. The gusset 14 may be formed from a multilayer panel 150 with a metal film 110 extending over the multilayer panel 150 along the opaque portion 24 and not extending over the multilayer panel 150 along the transparent window portion 26. That is, the metal film 110 inhibits or prevents light from passing through the opaque portion 24 whereas the transparent window portion 26 without the metal film 110 allows light to pass there through. The multilayer panel 150 may include a first transparent polymer layer 102, a second transparent polymer layer 106 and a third transparent polymer layer 108. In embodiments, the first transparent polymer layer 102, the second transparent polymer layer 106 and/or the third transparent polymer layer 108 of the gusset 114 may be formed from the same materials as the second transparent polymer layer 106 and/or the third transparent polymer layer 108 of the pouch body 12. For example, the first transparent polymer layer 102 of the gusset 14 may be formed from PET, the second transparent polymer layer 106 may be formed from NY, and the third transparent polymer layer may be formed from PE, e.g. LLDPE. In other embodiments, the first transparent polymer layer 102, the second transparent polymer layer 106 and/or the third transparent polymer layer 108 of the gusset 114 may not be formed from the same materials as the second transparent polymer layer 106 and/or the third transparent polymer layer 108 of the pouch body 12. Extending over the multilayer panel 150 along the opaque portion of the gusset 14 is the metal film or metal film 110. Accordingly, the metal film 110 is only present along a portion of the gusset 14 and where it is not present a transparent window portion 26 is provided. The metal film 110 of the gusset 14 may be formed from the same material as the metal layer 104 of the pouch body 12, e.g., Al. However, the metal film 110 of the gusset 14 may not be formed from the same material as the metal layer 104 of the pouch body 12.

Referring now to FIG. 5, a process for forming the gusset 14 is depicted. At step 200, a multilayer panel 150 is prepared for depositing a metal film along a portion of the gusset 14 to be opaque. It should be understood that the multilayer panel 150 is transparent and allows light to pass there through. At step 210, a mask 120 is placed over a portion of the gusset 14 that is to remain transparent and where a transparent window portion is to be positioned. After the mask 120 is placed over the portion of the gusset 14 to remain transparent, a portion of the multilayer panel 150 is metallized with a metal film 110 applied to portions of the gusset 14 not covered by the mask 120 at step 220 such that an opaque portion 24 is provided. The metal film 110 may be applied to the multilayer panel 150 using any known method or technique, illustratively including physical vapor deposition techniques, chemical vapor deposition techniques, painting techniques, and the like. At step 230, the mask 120 is removed from the multilayer panel 150 and the gusset 14 having an opaque portion 24 and a transparent window portion 26 is provided. The gusset 14 with the opaque portion 24 and transparent window portion 26 may then be joined to the pouch body 12 along the bottom seam 17 to form the flexible pouch 10 that can contain a product. It is understood that product may be placed within the flexible pouch 10 and the flexible pouch 10 sealed until opened by a consumer. Also, the gusset 14 with the transparent window portion 26 allows a consumer to view the product within the flexible pouch 10 therethrough. Accordingly, a majority of the surface of the flexible pouch 10 includes a metal layer that protects the product from light, moisture, oxygen ingress, etc. through the pouch material. Also, with the flexible pouch 10 being a standup flexible pouch, light does not penetrate through the transparent window portion 26 when the flexible pouch 10 is in a standup position.

In embodiments, the transparent window portion 26 results in more than 70% of the total surface area of the flexible pouch 10 having an opaque surface. In some embodiments, the transparent window portion 26 results in more than 80% of the total surface area of the flexible pouch 10 having an opaque surface. In other embodiments, the transparent window portion 26 results in more than 90% of the total surface area of the flexible pouch 10 having an opaque surface. In still yet other embodiments, the transparent window portion 26 results in more than 95% of the total surface area of the flexible pouch 10 having an opaque surface. Also, less than 100% of the total surface area of the flexible pouch 10 may be an opaque surface. For example, less than 99% of the total surface area, less than 98% of the total surface area, less than 95% of the total surface area, less than 90% of the total surface area, or less than 80% of the total surface area of the flexible pouch 10 may be an opaque surface.

In embodiments, the transparent window portion 26 results in more than 30% of the total surface area of the gusset 14 being transparent. In some embodiments, the transparent window portion 26 results in more than 40% of the total surface area of the gusset 14 being transparent. In other embodiments, the transparent window portion 26 results in more than 50% of the total surface area of the gusset 14 being transparent. In still other embodiments, the transparent window portion 26 results in more than 60% of the total surface area of the gusset 14 being transparent. In still yet other embodiments, the transparent window portion 26 results in more than 70% of the total surface area of the gusset 14 being transparent. Also, less than 100% of the total surface area of the gusset 14 may be transparent. For example, less than 90% of the total surface area, less than 80% of the total surface area, less than 70% of the total surface area, less than 60% of the total surface area, less than 50% of the total surface area, less than 40% of the total surface area, less than 30% of the total surface area, or less than 30% of the total surface area of the gusset 14 may be transparent.

It should now be understood that standup flexible pouches add methods for making standup flexible pouches described herein may be utilized to protect product contained within a standup flexible pouch from exposure to light and the ingress of oxygen into the flexible pouch, and yet allow an individual such as a consumer view the product contained within the flexible pouch. It should also be understood that while the transparent window portion of the gusset may allow for light penetration and the ingress of oxygen, the low percentage of total surface area of the flexible pouch that is transparent results in a flexible pouch that provides suitable storage, e.g., fresh storage, of product in the flexible pouch for desired time periods, e.g., for one month, six months, one year, two years, five years, etc. Also, with the transparent window portion being included in the gusset of the flexible pouch, minimal light enters into the flexible pouch when is in a standup position, e.g., on a shelf in the standup position.

It is noted that the term “about” may be utilized herein to represent the inherent degree of uncertainty that may be attributed to any quantitative comparison, value, measurement, or other representation. This term is also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A flexible pouch for containing a product, the flexible pouch comprising:
a pouch body formed from an opaque multilayer panel, wherein the opaque multilayer panel is configured to protect the product contained in the flexible pouch from oxygen ingress into the flexible pouch; and
a gusset formed from a panel comprising an opaque portion and a transparent window portion, wherein the transparent window portion is configured for viewing the product within the flexible pouch.

2. The flexible pouch of claim 1, wherein the transparent window portion of the gusset formed from the panel comprises a plurality of transparent polymer layers and the opaque portion comprises a metal film extending over the plurality of transparent polymer layers.

3. The flexible pouch of claim 2, wherein the plurality of transparent polymer layers comprise a first layer formed from polyethylene terephthalate, a second layer formed from nylon and a third layer formed from polyethylene.

4. The flexible pouch of claim 3, wherein the metal film is formed from aluminum.

5. The flexible pouch of claim 1, wherein the opaque multilayer panel comprises a first transparent polymer layer, a layer of metal, a second transparent polymer layer, and a third transparent polymer layer.

6. The flexible pouch of claim 1, wherein the opaque multilayer panel comprises a layer of polyethylene terephthalate, a layer of metal, a layer of nylon, and a layer of polyethylene.

7. The flexible pouch of claim 6, wherein the layer of metal is sandwiched between the layer of polyethylene terephthalate and the layer of nylon.

8. The flexible pouch of claim 7, wherein the transparent window portion is positioned in a central region of the gusset.

9. A flexible pouch for containing a product, the flexible pouch comprising:
an opaque pouch body formed from a multilayer panel comprising a first transparent polymer layer, a metal layer, a second transparent polymer layer and a third transparent polymer layer, wherein the metal layer is opaque and sandwiched between the first transparent polymer layer and the second transparent polymer layer; and
a gusset formed from another multilayer panel, the gusset having an opaque portion with a metal film extending over the another multilayer panel and a transparent window portion without the metal film extending over the another multilayer panel.

10. The flexible pouch of claim 9, wherein the first transparent polymer layer is formed from polyethylene terephthalate, the metal layer is formed from aluminum, the second transparent polymer layer is formed from nylon, and the third transparent polymer layer is formed from polyethylene.

11. The flexible pouch of claim 9, wherein the another multilayer film comprises a transparent polyethylene terephthalate layer, a transparent nylon layer and a transparent polyethylene layer.

12. The flexible pouch of claim 11, wherein the metal layer extends across the transparent polyethylene terephthalate layer.

13. The flexible pouch of claim 12, wherein the metal layer is an innermost layer extending across the transparent polyethylene terephthalate layer.

14. A process for making a flexible pouch comprising:
forming a pouch body from an opaque panel;
forming a gusset from a multilayer panel comprising an opaque portion and a transparent window portion;
sealing the gusset to the pouch body to form the flexible pouch, wherein the transparent window portion of the gusset is configured for an individual to view a product within the flexible pouch.

15. The process of claim 14, wherein the opaque portion of the multilayer panel is formed by a metal layer extending across the multilayer panel.

16. The process of claim 15, wherein the metal layer is formed on the opaque portion by vapor deposition.

17. The process of claim 16, further comprising masking the transparent window portion of the multilayer panel while vapor depositing the metal layer onto the opaque portion of the multilayer panel.

18. The process of claim 14, further comprising forming the opaque panel from a polyethylene terephthalate layer, an aluminum layer, a nylon layer and a polyethylene layer.

19. The process of claim 18, wherein the aluminum layer is sandwiched between the polyethylene terephthalate layer and the nylon layer.

20. The process of claim 14, further comprising forming the multilayer panel from a polyethylene terephthalate layer, a nylon layer and a polyethylene layer, wherein a metal layer extends over the polyethylene terephthalate layer in the opaque portion.
